(19) United States
(12) Patent Application Publication
(10) Pub. No.: US 2016/0197225 A1
(43) Pub. Date: Jul. 7, 2016

(54) Device of monolithically integrated optoelectrics

(71) Applicant: Justin Payne, San Jose, CA (US)

(72) Inventor: Justin Payne, San Jose, CA (US)

(21) Appl. No.: 14/998,215

(22) Filed: Dec. 24, 2015

Related U.S. Application Data
(63) Continuation of application No. 14/043,694, filed on Oct. 1, 2013, now abandoned.
(60) Provisional application No. 61/708,598, filed on Oct. 1, 2012.

(51) Int. Cl. H01L 31/18

(52) U.S. Cl. CPC H01L 31/1804

(57) ABSTRACT

A method is disclosed for fabricating optoelectronic component structures and traditional circuit elements on a single silicon substrate. Specific examples of optoelectronic components include, but are not limited to: photodiode structures, light emitter structures and waveguide structures. Traditional circuit elements include transistors, diodes, resistors, capacitors and associated metalized interconnects. The method of fabrication is compatible with traditional CMOS, Bi-CMOS and Bipolar processing requirements and design rules. The method consists of a set of processing steps to allow hetero-epitaxial deposition of III-V compound semiconductor films on to a suitably prepared silicon surface, a set of processing steps to allow this deposited wafer to continue processing in a traditional CMOS, Bi-CMOS or Bipolar processing line without the risk of contamination, and a set of steps to allow the fabrication of p-n and p-i-n photodiode/detector structures in parallel with the traditional CMOS, Bi-CMOS or Bipolar processing flow that produces the traditional circuit elements and also a set of steps for producing dielectric waveguides and optically black isolation films. The disclosed method also allows for wafer level encapsulation and wafer level packaging of the as-fabricated integrated optoelectronic chip.

### CROSS-REFERENCES TO RELATED APPLICATIONS

The present invention claims priority to and is a continuation of U.S. application Ser. No. 14/043,694, filed Oct. 1, 2013, which claims priority to U.S. Provisional Application No. 61/708,598 filed Oct. 1, 2012, which are incorporated by reference herein for all purposes.

### FIELD OF THE INVENTION

The disclosed invention relates generally to the field of Silicon Integrated Optoelectronics. More specifically, the described method relates to the fabrication and packaging of sensors and optical emitters on silicon which are monolithically integrated with ASICs, drivers, power supplies or other control circuits.

### BACKGROUND OF THE INVENTION

Arrays of sensors and optical emitters of various types are in common use in a number of consumer and industrial applications. Such arrays typically require three different basic components. Light detectors are used to measure signals from the outside world, as well as to measure signals from a coupled light emitting source or sources. Light emitters are used to provide electromagnetic signals for the aforementioned detectors to enable the collection of reflectance and distance information, to name two common examples. Finally, control circuits in the form of an ASIC or ASICs, power supply and/or driver components are required to enable operation of the detector(s) and emitter(s), signal processing of the output from such detector(s) and communication with external processors or circuits.

Existing methods for manufacturing arrays of sensors involve multiple independent fabrication processes: one process for detectors, one process for light emitters and at a minimum one process to produce the control circuit or ASIC. It should be noted that in many cases logic circuits for control and communication, as well as power supply circuits and driver circuits are all required. In these cases often more than one process is employed to fabricate discrete circuit chips in support of realizing the functionality of the final optoelectronic module. The disclosed invention provides a method for manufacturing all necessary optoelectronic components including the optical emitter and electronic circuit components in one process flow, on a single silicon chip commonly used in Si technology.

The requirement of multiple separate fabrication processes leads to the processing of multiple silicon wafers for each desired sensor array. Although not a basic engineering issue in and of itself, the need to process multiple wafers for a single assembly results in a smaller quantity of wafers of a specialized type. This need for small quantities of several specialized wafer types reduces the economy of scale that is desirable in a high volume manufacturing line, thus increasing the manufacturing cost per sensor assembly. The disclosed invention addresses this concern by providing a means to fabricate an arbitrary number of desired sensors and circuits together as a single chip module on a single silicon substrate, resulting in a higher volume of a single wafer type during manufacturing, and gaining economy of scale. Traditional sensor assemblies composed of discrete optoelectronic and electronic circuit components require either a separate semiconductor package for each device, or a single package that includes all of the discrete components as a multi-chip module. All components must be properly aligned to each other, optically isolated from each other as needed, and connected to each other via wire bonds. As part of the packaging process each sensor component will need to be provided with a “window” of appropriate material to enable them to communicate with the outside world by light. All of these aspects of the packaging requirements serve to increase the cost and complexity of the package itself. The disclosed invention serves to reduce the packaging cost by providing a method for manufacturing all required optoelectronic and electronic circuit elements on a single silicon chip. Additionally, the disclosed invention reduces packaging cost by enabling wafer level packaging of the as-fabricated sensor-circuit array. One of the goals of this invention is to provide a method for integrating an arbitrary number of optoelectronic and electronic circuit elements with minimal increases to the cost of packaging the final assembly. In addition new functionality is possible due to the smaller size, higher sensitivity and more highly integrated component set of the chip.

A further goal of the present invention is to enable the monolithic integration of optoelectronic components including light emitter from UV to red spectral range and electronic circuits in a single silicon chip in order to realize a significant increase in the functionality and resultant end use applications that it is possible to manufacture.

### SUMMARY OF THE INVENTION

This patent discloses a method for fabricating optoelectronic and electronic component structures on a single silicon substrate. This method is generally applicable to the manufacture of any product requiring the integration of light detectors, light emitters and control circuits. The disclosed method is of particular interest for the manufacturing of monolithically integrated single-chip Ambient Light and Proximity Sensors for use in consumer products such as mobile handsets and tablet computers as well as for general lighting applications such as Intelligent Solid State Lighting. Additionally, such emitter and sensor combinations are useful for the implementation of a Lighting LAN as optical to electrical and electrical to optical transceiver devices.

In the most general form the disclosed method consists of a set of processing steps to enable parallel and/or series fabrication of III-V compound semiconductor films and structures on the same silicon substrate upon which more traditional dopant diffused p-i-n photodiodes, epitaxial Si p-i-n photodiodes and CMOS or Bipolar circuit elements are also fabricated.

The method involves starting material in the form of a silicon wafer with a crystallographic orientation of (100), (111) or (110).

Several process modules are executed on this starting substrate, with modules named as follows: ACTIVE, ENCAPSULATION, EPI, IMPLANT, DEPOSIT, WLP and CMOS.

Active:

The purpose of this module is to produce the III-V emitter and detector structures in the desired physical layout on the substrate surface. The substrate has a film of a suitable dielectric material deposited on both the front and back surfaces to serve as a mask to define “active” regions for subsequent III-V compound semiconductor hetero-epitaxial film deposition. Examples of suitable dielectric materials include, but are not limited to, SiO₂, SiN and SiON. One common technique for depositing such films is Low Pressure Chemical Vapor Deposition (LPCVD). Traditional lithography techniques involving the application of photoresist, exposure to a suitable light source, and subsequent development of the photoresist are used to define the desired regions for III-V deposition. Traditional dielectric wet etch chemistries including but not limited to BOE solutions, or Oxide and Nitride dry etch techniques such as RIE or ICP are used to remove the dielectric masking layer in the patterned regions to produce an exposed Si surface or surfaces suitable for subsequent III-V compound deposition. In the case of a silicon substrate with a (111) or (110) crystallographic orientation the as-patterned Si(111) surface revealed by the dielectric etching is suitable for depositing the desired III-V compound semiconductor films. For the case of Si(100) oriented starting material, wet or dry etching techniques are employed to produce either an Si(110) oriented surface or an Si(111) oriented surface to facilitate III-V compound deposition. One specific III-V film of interest for optoelectronic components is GaN, which can be deposited on Si(111) or Si(110) using the technique of MOCVD (metal-organic chemical vapor deposition), to name one example. At this stage the compound semiconductor film deposition is executed. Film growth conditions are chosen to minimize deposition on the dielectric masking layer and guarantee hetero-epitaxial deposition on the exposed and prepared silicon surface or surfaces. In the case of MOCVD as the deposition technique a suitable nucleation and buffer layer is employed, as is commonly known in the art. Such a buffer layer can consist of AlN or AlN with additional layers such as SiN and TiN. Regardless, the III-V compound thin films are subsequently deposited with their dopant type and doping levels chosen and the film compositions as well as total number of films chosen to realize the desired final optoelectronic component, be it a light emitting diode, a multiple quantum well structure for light emission in the form of a diode or diode laser, a p-i-n photodiode structure for absorbing light and providing or modulating an electrical signal, or even a self electro-optic device based on multiple quantum well structures for switching light signals.

Regardless of the desired structure being fabricated or the chosen compound semiconductor deposition technique, after the completion of deposition the wafer is processed through a suitable chemical mechanical polishing (CMP) process. The CMP removes any parasitic polycrystalline or amorphous deposition of the III-V compound which occurred on the masking dielectric layer, and stops on the masking dielectric layer, thus preparing the substrate for downstream processes.

Epi:

The purpose of this module is to deposit multiple single crystal silicon epitaxial layers with appropriate n-type, p-type and intrinsic doping levels to fabricate the epitaxial-Si deposited photodetector structures. Silicon epitaxial growth is processed by chemical vapor deposition (CVD) in a specific furnace that is designed for such processes.

Implant:

The purpose of this module is to properly pattern any regions of the device where crystalline Si implanted and diffused dopant p-n or p-i-n photodiodes will be fabricated, and complete the “deep” ion implantations to produce the large depletion regions such devices require for efficient operation. The desired shape and size of diffused photodiode structure is patterned on the wafer surface using traditional lithographic techniques of photoresist spinning, exposure and baking. The silicon surface is exposed to facilitate ion implantation by etching the dielectric masking/isolation layer using an appropriate RIE or ICP dry etching process. With the photoresist still present on the wafer surface, the n-type compensation ion implantation is processed to form the “n” and “i” regions of the diode structure.

Any of several dopant species typically employed to form n-wells for traditional CMOS or Bipolar processes may be used for this step, with P and As being the two most common examples. The photoresist is removed from the wafer surface using a solvent clean. The implanted dopant species are activated using either an RTP step, or if some diffusion of dopants is desired to shape the final profiles, by a traditional diffusion furnace step.

Encapsulation:

The purpose of this module is to provide any required thin film contact metallization to the deposited III-V active device structures, remove contaminants from the wafer surface and encapsulate the necessary surfaces and structures for CMOS line compatibility. The metals and materials that provide the best ohmic electrical performance for contacting to III-V materials are generally difficult to etch and pattern using traditional CMOS fabrication techniques, and so a photoresist lift-off process is employed to pattern the device area with contact structures while masking the desired open regions of the wafer from metal deposition. The wafer is suitably lithographically patterned with photoresist that has been baked to provide resistance to the metal deposition environment. The desired contact films are deposited in a high vacuum process, with e-beam evaporation and physical vapor deposition (PVD) being examples of two common techniques. In the case of a GaN alloy, a commonly used contact film stack consists of approximately 5 nm of Ni covered by approximately 15 nm of Au and capped with a top layer of 15 nm of Ti. Depending upon the specific application requirements, device structure, and choice of III-V compound composition many other choices of metals may be employed, with an arbitrary complexity to the chosen contact film stack. Some examples of other candidate metals include, but are not limited to: Co, Ti, Pd and Pt. After contact deposition the lift-off process is executed by placing the patterned wafer into a suitable agitated solvent bath to dissolve the photoresist from the wafer surface, thus removing the contact metallization that is present over the surface of the photoresist film and leaving only the metallization that is chemically bonded to the III-V compound semiconductor films. After the completion of lift-off the wafer is annealed to alloy the chosen contact metals and guarantee good electrical contact performance.

The wafer is next immersed in a bath containing a suitable wet chemistry to selectively remove the dielectric masking layer without etching the III-V film, contact metallization or underlying silicon substrate. This wet chemistry can be an off-the-shelf BOE mixture, or a custom concentration of aqueous HF, to name two suitable examples. Removal of the original dielectric masking layer through wet chemistry also removes the contaminants associated with both the III-V deposition process and the contact metallization process. Such contaminants will interfere with the fabrication of n-well and p-well structures for MOSFETs, MOS capacitors, diffused photodiodes and any other CMOS or Bipolar structure that requires precise modulation of the electrical properties of the silicon substrate to realize device functionality. After completion of the bulk bath immersion, the wafer is then processed through a traditional gate oxide clean process, with the typical equipment being a single wafer spin tool that sprays the desired cleaning solution and H₂O rinse over each individual wafer surface.

Next, depending upon the desired application one of two possible steps is executed. In one case the wafer is again encapsulated on both the front and back surfaces with a suitable dielectric film such as SiO₂ or SiN, possibly by LPCVD. In the other case only the front side of the wafer has a dielectric film deposited on its surface, with SiO₂, SiN or SiON being suitable candidate films and such traditional techniques as Plasma Enhanced Chemical Vapor Deposition (PECVD) or High Density Plasma CVD (HDP) being examples of suitable deposition techniques. The purpose of this step is to seal the III-V device structure layers chemically from the fab ambient. This prevents III-V compound species from contaminating of parts of the wafer surface where dopant implantation and diffusion will be used to fabricate photodiode or CMOS device structures. It also prevents III-V compound species from cross contaminating the processing fabrication line in general, which would reduce the yield of other CMOS processes that are running in parallel in the same manufacturing line.

CMOS:

The purpose of this module is to realize the CMOS circuitry required for any ASIC, driver, power supply or other traditional transistor-based devices required for functionality of the final integrated assembly. CMOS processes are a well-defined technology known to those of average ability in the art, thus detailed description of this portion of processing will not be provided aside from those specific steps necessary to fabricate the optoelectronic structures.

The “p” region of the p-n or p-i-n photodiode is fabricated during the p-well formation process step of the traditional CMOS line. This structure is realized through appropriate choice of lithographic masking in the required pattern layout, critical dimensions and regions of the device surface.

The CMOS process continues as per the chosen design rules through the final metallization and interconnect step.

After the final metallization step, and after the interlayer dielectric (ILD) encapsulation step, the processing steps for fabricating a deposited amorphous Si photodiode structure are executed.

The previous final or “top” metal layer has had the layout chosen to provide an appropriate electrode structure in the region of the device surface where a deposited amorphous Si optoelectronic component is desired.

Deposit:

The regions of the device where the a-Si optoelectronic components are to be fabricated are patterned using traditional lithographic techniques of photoresist application and patterning. The ILD is etched away from these patterned regions by a suitable RIE or ICP dry etching process. The photoresist and any etching polymer are removed from the wafer surface by a solvent clean.

Amorphous silicon (a-Si) is deposited on the wafer surface by either PVD or PECVD processes. The electrical properties of the a-Si are controlled by varying the dopant concentrations incorporated during the deposition process in order to realize the desired final optoelectronic structure, with p-n and p-i-n photodiodes as examples of two possible devices.

After a-Si deposition, the wafer is patterned with photoresist to protect the a-Si device active regions during the a-Si removal process, again using traditional lithographic patterning techniques. The exposed a-Si is removed by a suitable RIE or ICP etching process, which stops on the top ILD layer.

Next the wafer has a final encapsulation layer deposited on the surface. This layer will consist of a suitable dielectric material, with examples being SiO₂, SiN or SiON layer, or some combination of several layers. This layer might also consist of a polymeric material, with polyimide being an example of a possible material choice. The purpose for this layer will be to isolate the device from the ambient environment as well as to form an anti-reflective coating, as well as to control the spectrum of light that is able to impinge upon the surface of the various detector structures, should they be present.

Next the traditional CMOS processing Bond Pad open lithographic patterning and etch steps are performed.

WLP:

The purpose of this module is to execute the required processes for wafer level packaging of the integrated device assemblies either in fab, or in a suitable back end of line (BEOL) clean room. The device surface is prepared as necessary for wafer level packaging (WLP), should the chosen device array require such a packaging technique. The surface can be metalized in preparation for eutectic bonding, or glass frit can be applied in preparation for a frit bond.

After suitable surface preparation, the device wafer is ready to be bonded to a pre-patterned “cover” wafer to provide a hermetic seal against the environment over the lifetime of the device while also providing suitable windows for operation of light detector and emitter structures as necessary for realizing the functionality of the device array. This cover wafer is patterned with recesses to allow clearance for the device topography, as well as to provide an unbonded structure to facilitate exposure of the Bond Pads during the wafer dicing process. This will enable wire bonding of the Bond Pads to connections on the board where the device is ultimately mounted. One example of such an array is an integrated proximity and ambient light sensor where it is necessary for a light emitter to shine into the outside world, and necessary for a detector to be able to measure light from both the outside world ambient environment, as well as light from the integrated emitter structure that is reflected back from the outside world into the detector.

In one or more examples, the present invention discloses the following claims.
1) A method for fabricating optoelectronic structures on a silicon substrate.
2) The method in claim (1) for fabricating optoelectronic structures and electronic structures on a single silicon substrate.
3) The method in claim (1) where the optoelectronic structures are comprised of one or more silicon based light detector structures and one or more compound semiconductor based light emitter structures in the wavelength range from ultraviolet (UV) to infrared.
4) The method in claim (1) where the optoelectronic structures are comprised of one or more silicon based light detector structures, one or more deposited thin film light detector structures, and one or more compound semiconductor based light emitter structures.
5) The method in claim (1) where the optoelectronic structures are comprised of one or more silicon based light detector structures, one or more deposited thin film light detector structures, one or more compound semiconductor based light detector structures and one or more compound semiconductor based light emitter structures.
6) The method in claim (1) where the optoelectronic structures are comprised of one or more silicon based light detector structures, one or more compound semiconductor based light detector structures and one or more compound semiconductor based light emitter structures.
7) The method in claim (3) where the silicon based optoelectronic structures are comprised of p-n photodiodes.
8) The method in claim (3) where the silicon based optoelectronic structures are comprised of lateral p-n photodiodes.
9) The method in claim (3) where the silicon based optoelectronic structures are comprised of p-i-n photodiodes.
10) The method in claim (3) where the silicon based optoelectronic structures are comprised of lateral p-i-n photodiodes.
11) The method in claim (4) where the silicon based optoelectronic structures are comprised of p-n photodiodes.
12) The method in claim (4) where the silicon based optoelectronic structures are comprised of lateral p-n photodiodes.
13) The method in claim (4) where the silicon based optoelectronic structures are comprised of p-i-n photodiodes.
14) The method in claim (4) where the silicon based optoelectronic structures are comprised of lateral p-i-n photodiodes.
15) The method in claim (5) where the silicon based optoelectronic structures are comprised of p-n photodiodes.
16) The method in claim (5) where the silicon based optoelectronic structures are comprised of lateral p-n photodiodes.
17) The method in claim (5) where the silicon based optoelectronic structures are comprised of p-i-n photodiodes.
18) The method in claim (5) where the silicon based optoelectronic structures are comprised of lateral p-i-n photodiodes.
19) The method in claim (6) where the silicon based optoelectronic structures are comprised of p-n photodiodes.
20) The method in claim (6) where the silicon based optoelectronic structures are comprised of lateral p-n photodiodes.
21) The method in claim (6) where the silicon based optoelectronic structures are comprised of p-i-n photodiodes.
22) The method in claim (6) where the silicon based optoelectronic structures are comprised of lateral p-i-n photodiodes.
23) The method in claim (4) where the deposited thin film optoelectronic structures are comprised of p-n photodiodes.
24) The method in claim (4) where the deposited thin film optoelectronic structures are comprised of lateral p-n photodiodes.
25) The method in claim (4) where the deposited thin film optoelectronic structures are comprised of p-i-n photodiodes.
26) The method in claim (4) where the deposited thin film optoelectronic structures are comprised of lateral p-i-n photodiodes.
27) The method in claim (4) where the deposited thin film optoelectronic structures are comprised of deposited a-Si p-n photodiodes.
28) The method in claim (4) where the deposited thin film optoelectronic structures are comprised of deposited a-Si lateral p-n photodiodes.
29) The method in claim (4) where the deposited thin film optoelectronic structures are comprised of deposited a-Si p-i-n photodiodes.
30) The method in claim (4) where the deposited thin film optoelectronic structures are comprised of deposited a-Si lateral p-i-n photodiodes.
31) The method in claim (5) where the deposited thin film optoelectronic structures are comprised of p-n photodiodes.
32) The method in claim (5) where the deposited thin film optoelectronic structures are comprised of lateral p-n photodiodes.
33) The method in claim (5) where the deposited thin film optoelectronic structures are comprised of p-i-n photodiodes.
34) The method in claim (5) where the deposited thin film optoelectronic structures are comprised of lateral p-i-n photodiodes.
35) The method in claim (5) where the deposited thin film optoelectronic structures are comprised of deposited a-Si p-n photodiodes.
36) The method in claim (5) where the deposited thin film optoelectronic structures are comprised of deposited a-Si lateral p-n photodiodes.
37) The method in claim (5) where the deposited thin film optoelectronic structures are comprised of deposited a-Si p-i-n photodiodes.
38) The method in claim (5) where the deposited thin film optoelectronic structures are comprised of deposited a-Si lateral p-i-n photodiodes.
39) The method in claim (5) where the compound semiconductor optoelectronic structures are comprised of p-n photodiodes.
40) The method in claim (5) where the compound semiconductor optoelectronic structures are comprised of multiple quantum well (MQW) photodiodes.
41) The method in claim (6) where the compound semiconductor optoelectronic structures are comprised of p-n photodiodes.
42) The method in claim (6) where the compound semiconductor optoelectronic structures are comprised of multiple quantum well (MQW) photodiodes.
43) The method in claim (2) where the optoelectronic structures are comprised of one or more silicon based light detector structures and one or more compound semiconductor based light emitter structures with emission wavelength that span the range from ultraviolet (UV) to red.
44) The method in claim (2) where the optoelectronic structures are comprised of one or more silicon based light detector structures, one or more deposited thin film light detector structures, and one or more compound semiconductor based light emitter structures.
45) The method in claim (2) where the optoelectronic structures are comprised of one or more silicon based light detector structures, one or more deposited thin film light detector structures, one or more compound semiconductor based light detector structures and one or more compound semiconductor based light emitter structures.
46) The method in claim (2) where the optoelectronic structures are comprised of one or more silicon based light detector structures, one or more compound semiconductor based light detector structures and one or more compound semiconductor based light emitter structures with emission wavelengths that span the range from ultraviolet (UV) to red.
47) The method in claim (43) where the silicon based optoelectronic structures are comprised of p-n photodiodes.
48) The method in claim (43) where the silicon based optoelectronic structures are comprised of lateral p-n photodiodes.
49) The method in claim (43) where the silicon based optoelectronic structures are comprised of p-i-n photodiodes.
50) The method in claim (43) where the silicon based optoelectronic structures are comprised of lateral p-i-n photodiodes.
51) The method in claim (44) where the silicon based optoelectronic structures are comprised of p-n photodiodes.
52) The method in claim (44) where the silicon based optoelectronic structures are comprised of lateral p-n photodiodes.
53) The method in claim (44) where the silicon based optoelectronic structures are comprised of p-i-n photodiodes.
54) The method in claim (44) where the silicon based optoelectronic structures are comprised of lateral p-i-n photodiodes.
55) The method in claim (45) where the silicon based optoelectronic structures are comprised of p-n photodiodes.
56) The method in claim (45) where the silicon based optoelectronic structures are comprised of lateral p-n photodiodes.
57) The method in claim (45) where the silicon based optoelectronic structures are comprised of p-i-n photodiodes.
58) The method in claim (45) where the silicon based optoelectronic structures are comprised of lateral p-i-n photodiodes.
59) The method in claim (46) where the silicon based optoelectronic structures are comprised of p-n photodiodes.
60) The method in claim (46) where the silicon based optoelectronic structures are comprised of lateral p-n photodiodes.
61) The method in claim (46) where the silicon based optoelectronic structures are comprised of p-i-n photodiodes.
62) The method in claim (46) where the silicon based optoelectronic structures are comprised of lateral p-i-n photodiodes.
63) The method in claim (44) where the deposited thin film optoelectronic structures are comprised of p-n photodiodes.
64) The method in claim (44) where the deposited thin film optoelectronic structures are comprised of lateral p-n photodiodes.
65) The method in claim (44) where the deposited thin film optoelectronic structures are comprised of p-i-n photodiodes.
66) The method in claim (44) where the deposited thin film optoelectronic structures are comprised of lateral p-i-n photodiodes.
67) The method in claim (44) where the deposited thin film optoelectronic structures are comprised of deposited a-Si p-n photodiodes.
68) The method in claim (44) where the deposited thin film optoelectronic structures are comprised of deposited a-Si lateral p-n photodiodes.
69) The method in claim (44) where the deposited thin film optoelectronic structures are comprised of deposited a-Si p-i-n photodiodes.
70) The method in claim (44) where the deposited thin film optoelectronic structures are comprised of deposited a-Si lateral p-i-n photodiodes.
71) The method in claim (45) where the deposited thin film optoelectronic structures are comprised of p-n photodiodes.
72) The method in claim (45) where the deposited thin film optoelectronic structures are comprised of lateral p-n photodiodes.
73) The method in claim (45) where the deposited thin film optoelectronic structures are comprised of p-i-n photodiodes.
74) The method in claim (45) where the deposited thin film optoelectronic structures are comprised of lateral p-i-n photodiodes.
75) The method in claim (45) where the deposited thin film optoelectronic structures are comprised of deposited a-Si p-n photodiodes.
76) The method in claim (45) where the deposited thin film optoelectronic structures are comprised of deposited a-Si lateral p-n photodiodes.
77) The method in claim (45) where the deposited thin film optoelectronic structures are comprised of deposited a-Si p-i-n photodiodes.
78) The method in claim (45) where the deposited thin film optoelectronic structures are comprised of deposited a-Si lateral p-i-n photodiodes.
79) The method in claim (45) where the compound semiconductor optoelectronic structures are comprised of p-n photodiodes.
80) The method in claim (45) where the compound semiconductor optoelectronic structures are comprised of multiple quantum well (MQW) photodiodes.
81) The method in claim (46) where the compound semiconductor optoelectronic structures are comprised of p-n photodiodes.
82) The method in claim (46) where the compound semiconductor optoelectronic structures are comprised of multiple quantum well (MQW) photodiodes.
83) The method in claim (2) where the electronic structures are fabricated by a CMOS process.
84) The method in claim (2) where the electronic structures are fabricated by a Bi-CMOS process.
85) The method in claim (2) where the electronic structures are fabricated by a Bipolar process.
86) The method in claim (83) where the CMOS electronic structures are comprised of circuits for driving the emitter structures.
87) The method in claim (83) where the CMOS electronic structures are comprised of circuits for controlling the detector structures.
88) The method in claim (83) where the CMOS electronic structures are comprised of circuits for communicating with external devices or circuits.
89) The method in claim (83) where the CMOS electronic structures are comprised of circuits for driving the emitter structures and controlling the detector structures.
90) The method in claim (83) where the CMOS electronic structures are comprised of circuits for driving the emitter structures and communicating with external devices.
91) The method in claim (83) where the CMOS electronic structures are comprised of circuits for controlling the detector structures and communicating with external devices.
92) The method in claim (83) where the CMOS electronic structures are comprised of circuits for driving the emitter structures, controlling the detector structures and communicating with external devices.
93) The method in claim (84) where the Bi-CMOS electronic structures are comprised of circuits for driving the emitter structures.
94) The method in claim (84) where the Bi-CMOS electronic structures are comprised of circuits for controlling the detector structures.
95) The method in claim (84) where the Bi-CMOS electronic structures are comprised of circuits for communicating with external devices or circuits.
96) The method in claim (84) where the Bi-CMOS electronic structures are comprised of circuits for driving the emitter structures and controlling the detector structures.
97) The method in claim (84) where the Bi-CMOS electronic structures are comprised of circuits for driving the emitter structures and communicating with external devices.
98) The method in claim (84) where the Bi-CMOS electronic structures are comprised of circuits for controlling the detector structures and communicating with external devices.
99) The method in claim (84) where the Bi-CMOS electronic structures are comprised of circuits for driving the emitter structures, controlling the detector structures and communicating with external devices.
100) The method in claim (84) where the bipolar electronic structures are comprised of circuits for driving the emitter structures.
101) The method in claim (84) where the bipolar electronic structures are comprised of circuits for controlling the detector structures.
102) The method in claim (84) where the bipolar electronic structures are comprised of circuits for communicating with external devices or circuits.
103) The method in claim (84) where the bipolar electronic structures are comprised of circuits for driving the emitter structures and controlling the detector structures.
104) The method in claim (84) where the bipolar electronic structures are comprised of circuits for driving the emitter structures and communicating with external devices.
105) The method in claim (84) where the bipolar electronic structures are comprised of circuits for controlling the detector structures and communicating with external devices.
106) The method in claim (84) where the bipolar electronic structures are comprised of circuits for driving the emitter structures, controlling the detector structures and communicating with external devices.
107) The method in claim (1) where the compound semiconductor structures are formed on the (100) surface of the silicon substrate.
108) The method in claim (1) where the compound semiconductor structures are formed on the (110) surface of the silicon substrate.
109) The method in claim (1) where the compound semiconductor structures are formed on the (111) surface of the silicon substrate.
110) The method in claim (1) where the compound semiconductor structures are formed on the (100) surface of a silicon substrate having a (100) crystallographic orientation.
111) The method in claim (1) where the compound semiconductor structures are formed on the (110) surface of a silicon substrate having a (110) crystallographic orientation.
112) The method in claim (1) where the compound semiconductor structures are formed on the (111) surface of a silicon substrate having a (111) crystallographic orientation.
113) The method in claim (1) where the compound semiconductor structures are formed on the (110) surface of a silicon substrate having a (100) crystallographic orientation.
114) The method in claim (1) where the compound semiconductor structures are formed on the (111) surface of a silicon substrate having a (100) crystallographic orientation.
115) The method in claim (1) where the compound semiconductor structures are formed on the (111) surface of a silicon substrate having a (110) crystallographic orientation.
116) The method in claim (113) where the (110) surfaces are formed by wet etching.
117) The method in claim (114) where the (111) surfaces are formed by wet etching.
118) The method in claim (115) where the (111) surfaces are formed by wet etching.
119) The method in claim (113) where the (110) surfaces are formed by dry etching.
120) The method in claim (114) where the (111) surfaces are formed by dry etching.
121) The method in claim (115) where the (111) surfaces are formed by dry etching.
122) The method in claim (3) having the compound semiconductor structures comprised of a III-V binary alloy.
123) The method in claim (3) having the compound semiconductor structures comprised of a III-V ternary alloy.
124) The method in claim (122) having the III-V binary alloy as a stoichiometric film of GaN.
125) The method in claim (123) having the III-V ternary alloy as a film of III-N alloys of varying composition and elemental ratios.
126) The method in claim (122) having a light emitter structure comprised of a p-n junction of III-V binary alloy with a multiple quantum well region of a III-V ternary alloy.
127) The method in claim (123) having a light emitter structure comprised of a p-n junction of III-V ternary alloy with a multiple quantum well region of a III-V ternary alloy.
128) The method in claim (126) having a light emitter structure comprised of a p-n junction of GaN with a multiple quantum well region comprised of an InGaN or similar III-N alloy of varying compositions.
129) The method in claim (126) having a light emitter structure comprised of a p-n junction of GaN with a multiple quantum well region comprised of an AlGaN alloy of varying compositions.
130) The method in claim (126) having a light emitter structure comprised of a p-n junction of GaN with a multiple quantum well region comprised of an GaN or similar III-N material alloy of varying compositions.
131) The method in claim (127) having a light emitter structure comprised of a p-n junction of GaN or similar III-N material with a multiple quantum well region comprised of an InGaN alloy of varying compositions.
132) The method in claim (127) having a light emitter structure comprised of a p-n junction of GaN or similar III-N material with a multiple quantum well region comprised of an AlGaN alloy of varying compositions.
133) The method in claim (127) having a light emitter structure comprised of a p-n junction of GaN or similar III-N material with a multiple quantum well region comprised of a GaAsN alloy of varying compositions.
134) The method in claim (122) having a light detector structure comprised of a p-n junction of III-V binary alloy with a multiple quantum well region of a III-V ternary alloy.
135) The method in claim (123) having a light detector structure comprised of a p-n junction of III-V ternary alloy with a multiple quantum well region of a III-V ternary alloy.
136) The method in claim (134) having a light detector structure comprised of a p-n junction of GaN with a multiple quantum well region comprised of an InGaN alloy of varying compositions.
137) The method in claim (134) having a light detector structure comprised of a p-n junction of GaN with a multiple quantum well region comprised of an AlGaN alloy of varying compositions.
138) The method in claim (134) having a light detector structure comprised of a p-n junction of GaN with a multiple quantum well region comprised of a GaAsN alloy of varying compositions.
139) The method in claim (135) having a light detector structure comprised of a p-n junction of GaN or similar III-N material with a multiple quantum well region comprised of an InGaN alloy of varying compositions.
140) The method in claim (135) having a light detector structure comprised of a p-n junction of GaN or similar III-N material with a multiple quantum well region comprised of an AlGaN alloy of varying compositions.
141) The method in claim (135) having a light detector structure comprised of a p-n junction of GaN or similar III-N material with a multiple quantum well region comprised of a GaAsN alloy of varying compositions.
142) The method in claim (4) having the compound semiconductor structures comprised of a III-V binary alloy.
143) The method in claim (4) having the compound semiconductor structures comprised of a III-V ternary alloy.
144) The method in claim (142) having the III-V binary alloy as a stoichiometric film of GaN.
145) The method in claim (143) having the III-V ternary alloy as a film of AlGaN of varying composition and elemental ratios.
146) The method in claim (142) having a light emitter structure comprised of a p-n junction of III-V binary alloy with a multiple quantum well region of a III-V ternary alloy.
147) The method in claim (143) having a light emitter structure comprised of a p-n junction of III-V ternary alloy with a multiple quantum well region of a III-V ternary alloy.
148) The method in claim (146) having a light emitter structure comprised of a p-n junction of GaN with a multiple quantum well region comprised of an InGaN alloy of varying compositions.
149) The method in claim (146) having a light emitter structure comprised of a p-n junction of GaN with a multiple quantum well region comprised of an AlGaN alloy of varying compositions.
150) The method in claim (146) having a light emitter structure comprised of a p-n junction of GaN with a multiple quantum well region comprised of an GaAsN alloy of varying compositions.
151) The method in claim (147) having a light emitter structure comprised of a p-n junction of GaN or similar III-N material with a multiple quantum well region comprised of an InGaN alloy of varying compositions.
152) The method in claim (147) having a light emitter structure comprised of a p-n junction of GaN or similar III-N material with a multiple quantum well region comprised of an AlGaN alloy of varying compositions.
153) The method in claim (147) having a light emitter structure comprised of a p-n junction of GaN or similar III-N material with a multiple quantum well region comprised of a GaAsN alloy of varying compositions.
154) The method in claim (142) having a light detector structure comprised of a p-n junction of III-V binary alloy with a multiple quantum well region of a III-V ternary alloy.
155) The method in claim (143) having a light detector structure comprised of a p-n junction of III-V ternary alloy with a multiple quantum well region of a III-V ternary alloy.
156) The method in claim (144) having a light detector structure comprised of a p-n junction of GaN with a multiple quantum well region comprised of an InGaN alloy of varying compositions.
157) The method in claim (154) having a light detector structure comprised of a p-n junction of GaN with a multiple quantum well region comprised of an AlGaN alloy of varying compositions.
158) The method in claim (154) having a light detector structure comprised of a p-n junction of GaN with a multiple quantum well region comprised of a GaAsN alloy of varying compositions.
159) The method in claim (155) having a light detector structure comprised of a p-n junction of GaN or similar III-N material with a multiple quantum well region comprised of an InGaN alloy of varying compositions.
160) The method in claim (155) having a light detector structure comprised of a p-n junction of GaN or similar III-N material with a multiple quantum well region comprised of an AlGaN alloy of varying compositions.
161) The method in claim (155) having a light detector structure comprised of a p-n junction of GaN or similar III-N material with a multiple quantum well region comprised of a GaAsN alloy of varying compositions.
162) The method in claim (5) having the compound semiconductor structures comprised of a III-V binary alloy.
163) The method in claim (5) having the compound semiconductor structures comprised of a III-V ternary alloy.
164) The method in claim (162) having the III-V binary alloy as a stoichiometric film of GaN.
165) The method in claim (163) having the III-V ternary alloy as a film of AlGaN of varying composition and elemental ratios.
166) The method in claim (162) having a light emitter structure comprised of a p-n junction of III-V binary alloy with a multiple quantum well region of a III-V ternary alloy.
167) The method in claim (163) having a light emitter structure comprised of a p-n junction of III-V ternary alloy with a multiple quantum well region of a III-V ternary alloy.
168) The method in claim (166) having a light emitter structure comprised of a p-n junction of GaN with a multiple quantum well region comprised of an InGaN alloy of varying compositions.
169) The method in claim (166) having a light emitter structure comprised of a p-n junction of GaN with a multiple quantum well region comprised of an AlGaN alloy of varying compositions.
170) The method in claim (166) having a light emitter structure comprised of a p-n junction of GaN with a multiple quantum well region comprised of an GaAsN alloy of varying compositions.
171) The method in claim (167) having a light emitter structure comprised of a p-n junction of GaN or similar III-N material with a multiple quantum well region comprised of an InGaN alloy of varying compositions.
172) The method in claim (167) having a light emitter structure comprised of a p-n junction of GaN or similar III-N material with a multiple quantum well region comprised of an AlGaN alloy of varying compositions.
173) The method in claim (167) having a light emitter structure comprised of a p-n junction of GaN or similar III-N material with a multiple quantum well region comprised of a GaAsN alloy of varying compositions.
174) The method in claim (162) having a light detector structure comprised of a p-n junction of III-V binary alloy with a multiple quantum well region of a III-V ternary alloy.
175) The method in claim (163) having a light detector structure comprised of a p-n junction of III-V ternary alloy with a multiple quantum well region of a III-V ternary alloy.
176) The method in claim (164) having a light detector structure comprised of a p-n junction of GaN with a multiple quantum well region comprised of an InGaN alloy of varying compositions.
177) The method in claim (174) having a light detector structure comprised of a p-n junction of GaN with a multiple quantum well region comprised of an AlGaN alloy of varying compositions.
178) The method in claim (174) having a light detector structure comprised of a p-n junction of GaN with a multiple quantum well region comprised of a GaAsN alloy of varying compositions.
179) The method in claim (175) having a light detector structure comprised of a p-n junction of GaN or similar III-N material with a multiple quantum well region comprised of an InGaN alloy of varying compositions.
180) The method in claim (175) having a light detector structure comprised of a p-n junction of GaN or similar III-N material with a multiple quantum well region comprised of an AlGaN alloy of varying compositions.
181) The method in claim (175) having a light detector structure comprised of a p-n junction of GaN or similar III-N material with a multiple quantum well region comprised of a GaAsN alloy of varying compositions.
182) The method in claim (6) having the compound semiconductor structures comprised of a III-V binary alloy.
183) The method in claim (6) having the compound semiconductor structures comprised of a III-V ternary alloy.
184) The method in claim (182) having the III-V binary alloy as a stoichiometric film of GaN.
185) The method in claim (183) having the III-V ternary alloy as a film of AlGaN of varying composition and elemental ratios.
186) The method in claim (182) having a light emitter structure comprised of a p-n junction of III-V binary alloy with a multiple quantum well region of a III-V ternary alloy.
187) The method in claim (183) having a light emitter structure comprised of a p-n junction of III-V ternary alloy with a multiple quantum well region of a III-V ternary alloy.
188) The method in claim (186) having a light emitter structure comprised of a p-n junction of GaN with a multiple quantum well region comprised of an InGaN alloy of varying compositions.
189) The method in claim (186) having a light emitter structure comprised of a p-n junction of GaN with a multiple quantum well region comprised of an AlGaN alloy of varying compositions.
190) The method in claim (186) having a light emitter structure comprised of a p-n junction of GaN with a multiple quantum well region comprised of an GaAsN alloy of varying compositions.
191) The method in claim (187) having a light emitter structure comprised of a p-n junction of GaN or similar III-N material with a multiple quantum well region comprised of an InGaN alloy of varying compositions.
192) The method in claim (187) having a light emitter structure comprised of a p-n junction of GaN or similar III-N material with a multiple quantum well region comprised of an AlGaN alloy of varying compositions.
193) The method in claim (187) having a light emitter structure comprised of a p-n junction of GaN or similar III-N material with a multiple quantum well region comprised of a GaAsN alloy of varying compositions.
194) The method in claim (182) having a light detector structure comprised of a p-n junction of III-V binary alloy with a multiple quantum well region of a III-V ternary alloy.
195) The method in claim (183) having a light detector structure comprised of a p-n junction of III-V ternary alloy with a multiple quantum well region of a III-V ternary alloy.
196) The method in claim (194) having a light detector structure comprised of a p-n junction of GaN with a multiple quantum well region comprised of an InGaN alloy of varying compositions.
197) The method in claim (194) having a light detector structure comprised of a p-n junction of GaN with a multiple quantum well region comprised of an AlGaN alloy of varying compositions.
198) The method in claim (194) having a light detector structure comprised of a p-n junction of GaN with a multiple quantum well region comprised of a GaAsN alloy of varying compositions.
199) The method in claim (195) having a light detector structure comprised of a p-n junction of GaN or similar III-N material with a multiple quantum well region comprised of an InGaN alloy of varying compositions.
200) The method in claim (195) having a light detector structure comprised of a p-n junction of GaN or similar III-N material with a multiple quantum well region comprised of an AlGaN alloy of varying compositions.
201) The method in claim (195) having a light detector structure comprised of a p-n junction of GaN or similar III-N material with a multiple quantum well region comprised of a GaAsN alloy of varying compositions.
202) The method in claim (3) having the silicon based optoelectronic structures comprised of doped crystalline Si.
203) The method in claim (202) where the doped regions of crystalline Si are created by ion implantation followed by implanted dopant electrical activation.
204) The method in claim (203) having the dopant species as B, As and P or combinations of B, As and P.
205) The method in claim (4) having the silicon based optoelectronic structures comprised of doped crystalline Si.
206) The method in claim (205) where the doped regions of crystalline Si are created by ion implantation followed by implanted dopant electrical activation.
207) The method in claim (206) having the dopant species as B, As and P or combinations of B, As and P.
208) The method in claim (5) having the silicon based optoelectronic structures comprised of doped crystalline Si.
209) The method in claim (208) where the doped regions of crystalline Si are created by ion implantation followed by implanted dopant electrical activation.
210) The method in claim (209) having the dopant species as B, As and P or combinations of B, As and P.
211) The method in claim (6) having the silicon based optoelectronic structures comprised of doped crystalline Si.
212) The method in claim (211) where the doped regions of crystalline Si are created by ion implantation followed by implanted dopant electrical activation.
213) The method in claim (212) having the dopant species as B, As and P or combinations of B, As and P.
214) The method in claim (4) having the deposited thin film detector structures are comprised of amorphous silicon (a-Si).
215) The method in claim (214) having the a-Si films deposited by plasma enhanced chemical vapor deposition (PECVD).
216) The method in claim (214) having the a-Si films deposited by physical vapor deposition (PVD).
217) The method in claim (5) having the deposited thin film detector structures are comprised of amorphous silicon (a-Si).
218) The method in claim (217) having the a-Si films deposited by plasma enhanced chemical vapor deposition (PECVD).
219) The method in claim (218) having the a-Si films deposited by physical vapor deposition (PVD).
220) The method in claim (1) having the optoelectronic structures optically isolated from each other by a thin film optically black coating.
221) The method in claim (220) having the optically black thin film comprised of amorphous carbon (a-C).
222) The method in claim (1) having the optoelectronic structures encapsulated by an anti-reflective coating.
223) The method in claim (222) having the anti-reflective coating comprised of silicon oxynitride (SiON).
224) The method in claim (222) having the anti-reflective coating comprised of silicon nitride (SiN).
225) The method in claim (222) having the anti-reflective coating comprised of silicon dioxide (SiO₂).
226) The method in claim (1) having the optoelectronic structures encapsulated by a wafer level packaging process.
227) The method in claim (226) having the wafer level package comprised of a cover wafer bonded to the silicon substrate.
228) The method in claim (227) having the cover wafer comprised of SiO₂.
229) The method in claim (227) having the bond between the cover wafer and silicon substrate comprised of a glass frit sealing layer.
230) The method in claim (227) having the bond between the cover wafer and silicon substrate comprised of a eutectic alloy.
231) The method in claim (2) having the combined optoelectronic and electronic structures encapsulated by a wafer level packaging process.
232) The method in claim (231) having the wafer level package comprised of a cover wafer bonded to the silicon substrate.
233) The method in claim (232) having the cover wafer comprised of SiO₂.
234) The method in claim (232) having the bond between the cover wafer and silicon substrate comprised of a glass frit sealing layer.
235) The method in claim (232) having the bond between the cover wafer and silicon substrate comprised of a eutectic alloy.
236) The method in claim (1) where the optoelectronic devices comprise compound semiconductor emitters, compound semiconductor detectors, silicon detectors, deposited silicon detectors and wave-guide structures that optically couple the emitters to the detectors, forming an integrated optical interconnect.
237) The method in claim (1) where the optoelectronic devices comprise compound semiconductor emitters, compound semiconductor detectors, silicon detectors, deposited silicon detectors and wave-guide structures that optically couple the emitters to the detectors, forming an optically isolated electrical switch and signal transferring device referred to as an “opto-isolator”.
238) The method in claim (1) having the silicon substrate comprised of a SOI wafer.
239) The method in claim (238) having the compound semiconductor emitters fabricated in the SOI layer.
240) The method in claim (238) having the compound semiconductor detectors fabricated in the SOI layer.
241) The method in claim (238) having at least one of the crystalline silicon detector structures fabricated in the SOI layer.
242) The method in claim (238) having at least one of the crystalline silicon detector structures fabricated in the bulk silicon wafer underneath the SOI layer.
243) The method in claim (238) having at least one of the amorphous silicon detector structures fabricated over the SOI layer surface.
244) The method in claim (238) having at least one of the amorphous silicon detector structures fabricated over the bulk Si layer surface but under the SOI layer surface.
245) The method in claim (4) where the deposited thin film optoelectronic structures are comprised of epitaxial Si p-n photodiodes.
246) The method in claim (4) where the deposited thin film optoelectronic structures are comprised of epitaxial Si lateral p-n photodiodes.
247) The method in claim (4) where the deposited thin film optoelectronic structures are comprised of epitaxial Si p-i-n photodiodes.
248) The method in claim (4) where the deposited thin film optoelectronic structures are comprised of epitaxial Si lateral p-i-n photodiodes.
249) The method in claim (5) where the deposited thin film optoelectronic structures are comprised of epitaxial Si p-n photodiodes.
250) The method in claim (5) where the deposited thin film optoelectronic structures are comprised of epitaxial Si lateral p-n photodiodes.
251) The method in claim (5) where the deposited thin film optoelectronic structures are comprised of epitaxial Si p-i-n photodiodes.
252) The method in claim (5) where the deposited thin film optoelectronic structures are comprised of epitaxial Si lateral p-i-n photodiodes.

### BRIEF DESCRIPTION OF THE DRAWINGS

FIG. 1 illustrates the starting material for one preferred embodiment of the invention both top down as well as in cross section through line 51-51. In this case the material is a silicon substrate with a (100) crystallographic orientation 1 that has had SiO₂ thermally grown on the front and back sides to serve as encapsulation ILD1 2.

FIG. 2 contains a top down view as well as a cross section through line 51-51 illustrating one chosen geometrical layout for a compound semiconductor optoelectronic element region 7 with etched Si open trenches 3 having sidewall surfaces of a (110) crystallographic orientation 4.

FIG. 3 illustrates the appearance of the substrate after processing through III-V semiconductor deposition both top down as well as in cross section through line 51-51. In this particular embodiment hetero-epitaxial regions of GaN or similar III-N material 5 are formed on the sidewalls 4, and GaN or similar III-N material polycrystals 6 are formed on the encapsulation ILD1 2.

FIG. 4 illustrates the appearance of the substrate after processing through chemical mechanical polishing, p-contact patterning, metallization, resist lift-off and clean both top down and in cross section through line 51-51. A p-contact 8 is formed on the surfaces of the compound semiconductor hetero-epitaxial regions 5.

FIG. 5 illustrates the substrate after encapsulation ILD1 2 removal etching and surface cleaning both top down as well as in cross section through line 51-51.

FIG. 6 illustrates the substrate after the deposition of encapsulation ILD2 9 both top down as well as in cross section through line 51-51.

FIG. 7 illustrates both top down and in cross section through line 52-52 the definition of the crystalline silicon optoelectronic element region 10 after the completion of n-well 11 lithographic patterning, etching, ion implantation and clean.

FIG. 8 illustrates both top down and in cross section through line 52-52 the substrate after completion of p-well 12 lithographic patterning, etching, ion implantation and clean. Also visible is the CMOS region 13 of the substrate that is being formed in parallel with optoelectronic element processing.

FIG. 9 illustrates both top down and in cross section through line 53-53 the definition of the deposited silicon optoelectronic element region 14 that occurs after completion of CMOS Top Metal 15 and Passivation ILD 16 deposition.

FIG. 10 illustrates both top down and in cross section through line 53-53 the substrate after completion of n-type and intrinsic a-Si 17 deposition, lithographic patterning, etch and clean.

FIG. 11 illustrates both top down and in cross section through line 53-53 the substrate after completion of p-type a-Si 18 deposition, lithographic patterning, etch and clean.

FIG. 12 illustrates both top down and in cross section through line 53-53 the substrate after dielectric anti-reflective coating and sensor passivation 19 deposition.

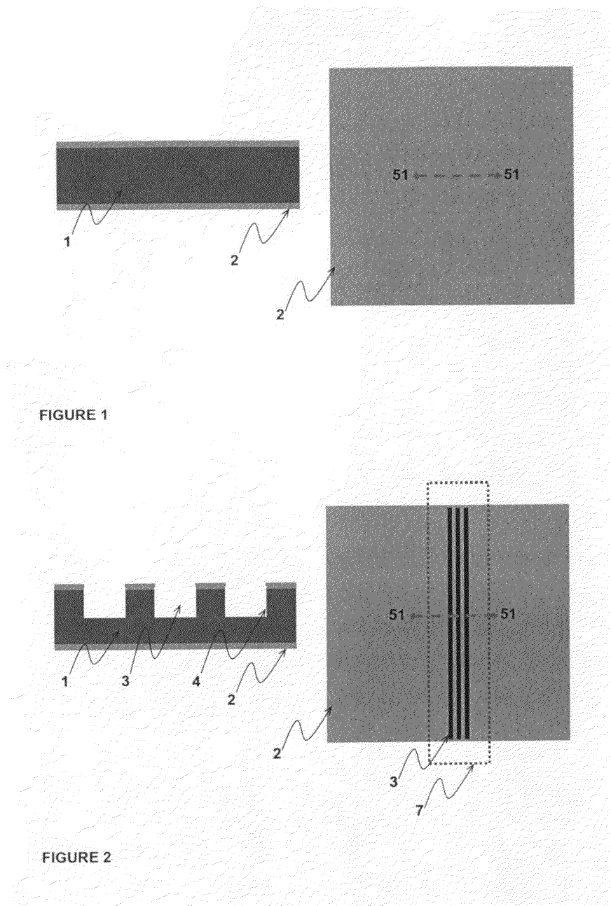

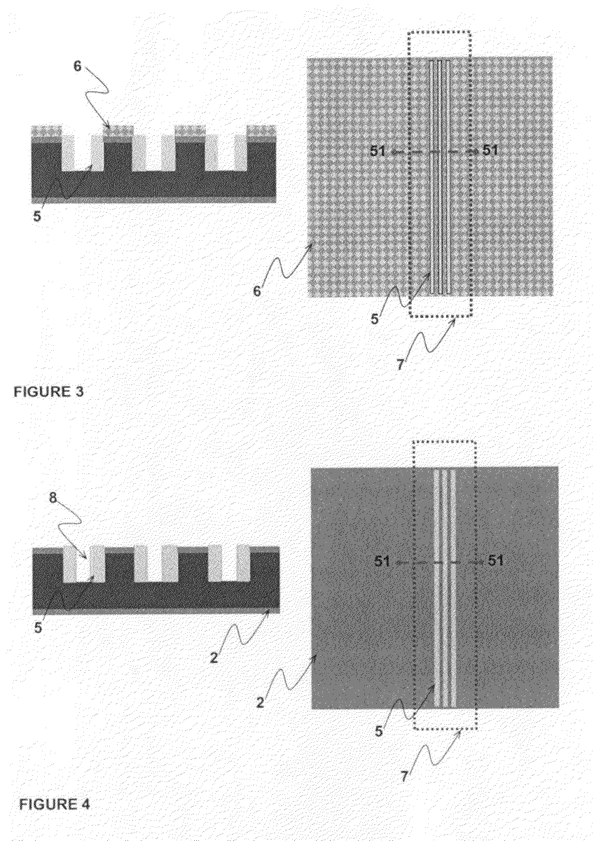

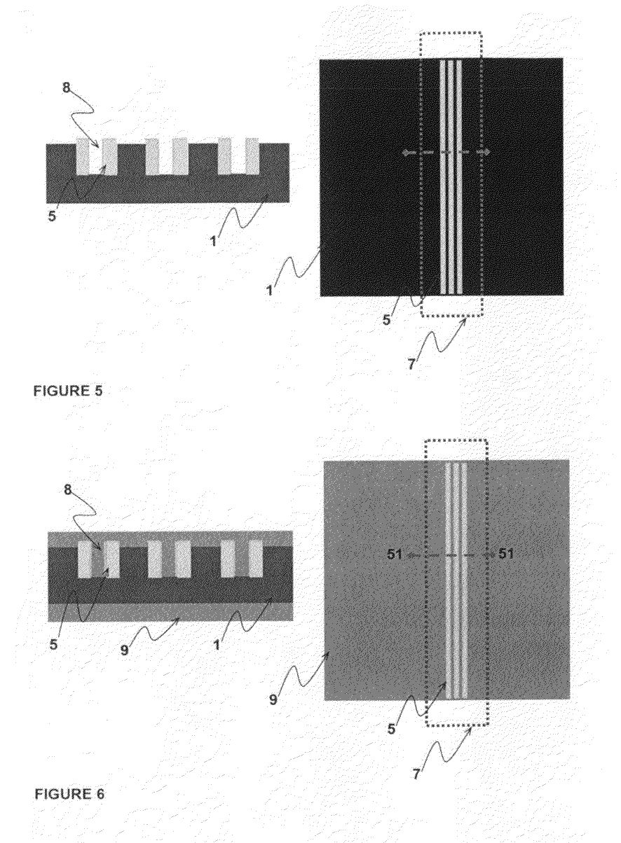

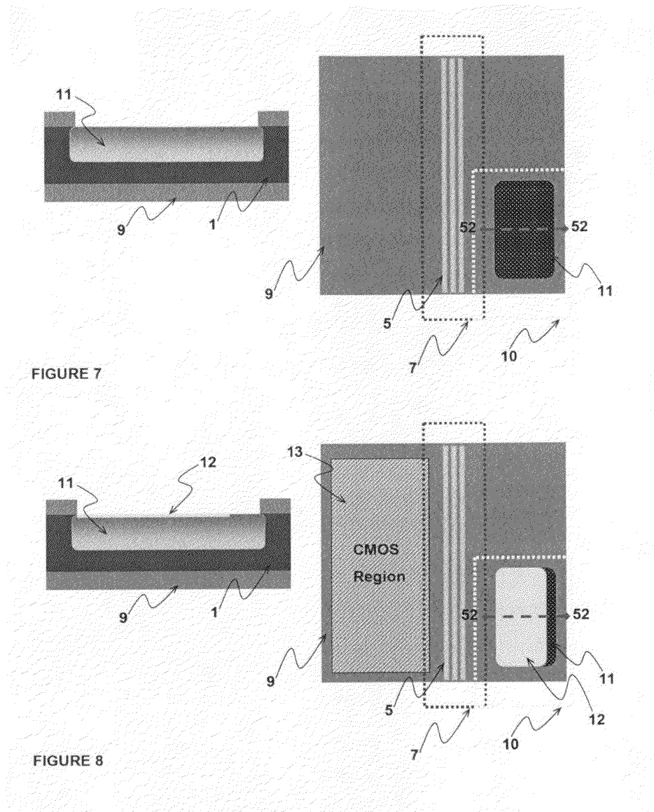

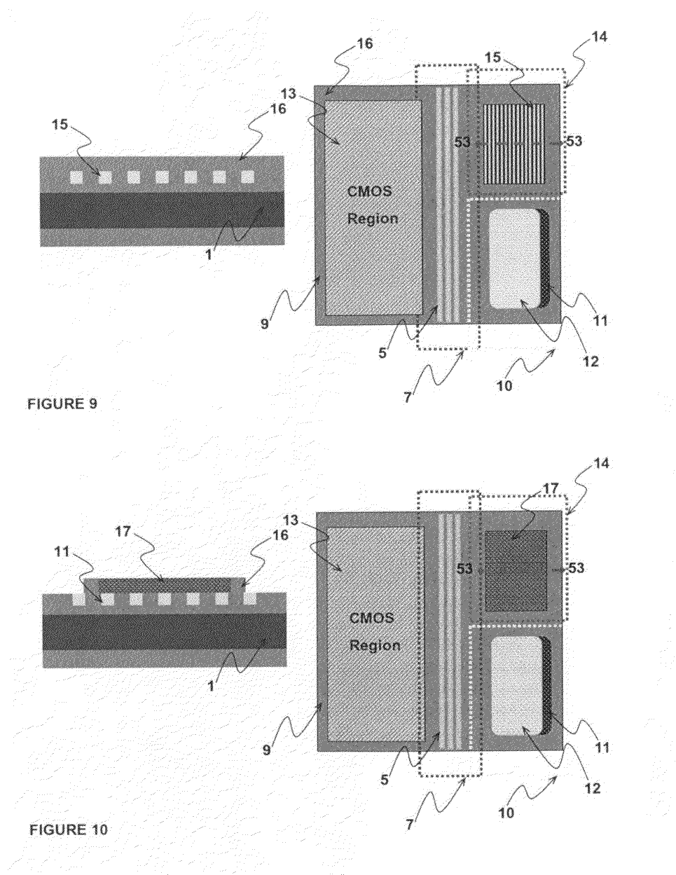

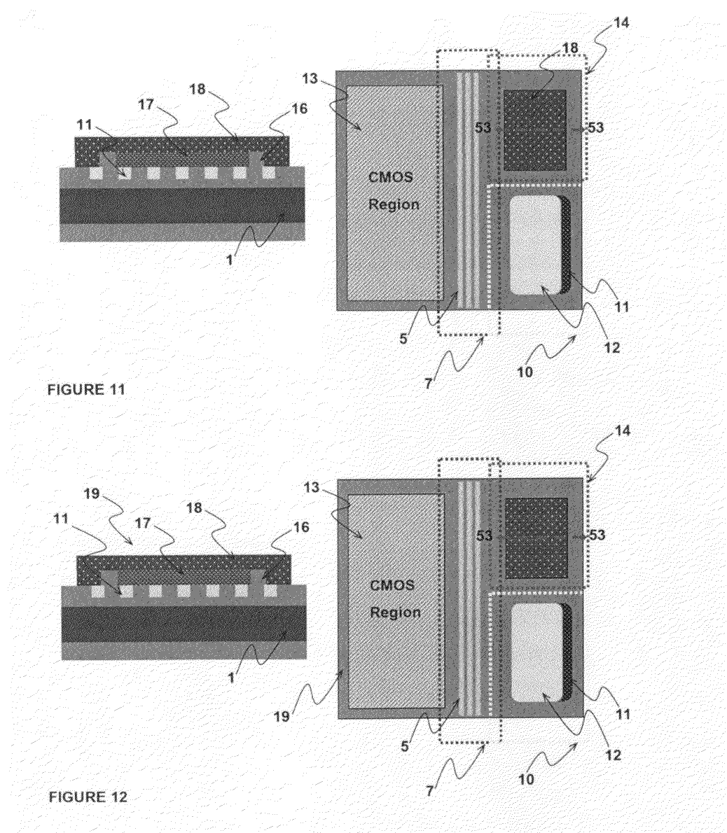

What is claimed is the following:

1. A method for fabricating optoelectronic structures on a silicon substrate.
